(19) United States
(12) Patent Application Publication
(10) Pub. No.: US 2007/0159371 A1
(43) Pub. Date: Jul. 12, 2007

(54) Wireless audio data transmitting and receiving apparatus using human body

(75) Inventors: Seong-Jun Song, Daejeon (KR); Seung Jin Lee, Daejeon (KR); Hoi-Jun Yoo, Daejeon (KR)

Correspondence Address: OLIFF & BERRIDGE, PLC, P.O. BOX 19928, ALEXANDRIA, VA, 22320, US

(73) Assignee: KOREA ADVANCED INSTITUTE OF SCIENCE AND TECHNOLOGY, DAEJEON (KR)

(21) Appl. No.: 11/637,727

(22) Filed: Dec. 13, 2006

(30) Foreign Application Priority Data
Jan. 12, 2006 (KR) 10-2006-3629

(51) Int. Cl. H03M 1/12

(52) U.S. Cl. 341/155

(57) ABSTRACT

Wireless audio data transmitting and receiving apparatus using human body is disclosed. An audio signal outputted from a portable audio player is converted by the digital audio interface technology without a wire or an antenna, is transferred through human body using only a single signal electrode at high speed, and the audio signal transferred through the human body is received to listen through an earphone. Thus, the inconvenient wire is removed to improve the convenience to use and the antenna which has a difficulty due to the size and the installation is not required. Moreover, since additional encoding and decoding for the reduction of the transfer rate are not required so that the high speed transfer is enabled and the power consumption can be reduced, components and/or a battery can be reduced in size and can be minimized.

### BACKGROUND OF THE INVENTION

1. Field of the Invention

The present invention relates to a wireless audio data communication apparatus using human body, and more particularly, to a wireless audio data transmitting and receiving apparatus using human body for converting an audio signal that is outputted from a portable audio player with a digital audio interfacing technology without a wire or an antenna to transmit the converted audio signal through the human body at high speed using a single signal electrode and for receiving the audio signal transmitted through the human body to listen to the signal through an earphone, a headphone, or the like.

2. Description of the Related Art

In general, methods of listening to an audio signal outputted from a portable cellular phone, a portable audio player, or the like, are roughly divided into: a wired type of connecting the audio player to an earphone with a copper wire to listen to the audio signal; and a wireless type of connecting the audio player to the earphone via wireless line using a radio frequency (RF) signal to listen to the audio signal.

The wired type method can be achieved by low costs and by using low power and has advantages of listening to high quality audio signal without external noise interference. However, the wired type is inconvenient to use in human body area and may have a spatial restriction.

Thus, in order to solve this inconvenience and spatial restriction, a short-range RF transmitting apparatus such as Bluetooth has been developed.

FIG. 1 is a block diagram illustrating a conventional wireless audio data transmitting and receiving apparatus using an RF signal.

As illustrated, an audio signal reproduced by a microphone 11, an audio player 10 such as an MP3 player (not shown), or a cellular phone (not shown) in which the microphone 11 or the MP3 player is installed is converted into an RF signal to be transmitted through air, and a weak RF signal that is transmitted through air is received to be recovered so that a speaker 37 reproduces the recovered audio signal.

In this case, a transmitting unit 20 includes an analog/digital (A/D) converter 21 to convert the audio signal outputted from the audio player 10 into a digital signal, a memory 22 and a microcontroller 23 to reduce a transmission error and to process a communication protocol, a baseband processor 24 to serve as a MODEM, and an RF transceiver 25 to recover the converted digital signal into an RF signal and to effectively transmit the RF signal through air via an antenna.

Moreover, a receiver 30 includes an RF transceiver 31 to detect the RF signal that becomes weak due to a path loss and a multipath effect through a receiver antenna, to amplify the detected RF signal, and to select only the desired signal from several RF signals to recover, a baseband processor 32 having a MODEM function, a memory 34 and a microcontroller 33 to process a communication protocol, a digital/analog (D/A) converter 35 to convert the recovered digital signal into an audio signal, and an amplifier 36 to effectively transmit the audio signal to the speaker 37.

However, the RF audio data transmitting apparatus increases power consumption due to the additional requirement of the RF transceivers 25 and 31, the baseband processors 24 and 32, the memories 22 and 34, and the microcontrollers 23 and 33.

Moreover, since the RF transmission is easily affected by external noise interference and requires additional encoding and decoding process because low speed transmission only is enabled due to the transmission error and the restriction for the band width, manufacturing costs are increased, there is a problem for a battery due to the requirement of additional power consumption, and it is difficult to minimize.

### SUMMARY OF THE INVENTION

Therefore, the present invention has been made in view of the above and/or other problems, and it is an aspect of the present invention to provide a wireless audio data transmitting and receiving apparatus using human body for converting an audio signal that is outputted from a portable audio player with a digital audio interfacing technology without a wire or an antenna to transmit the converted audio signal through the human body at high speed using a single signal electrode and for receiving the audio signal transmitted through the human body to listen to a signal through an earphone, a headphone, or the like.

In accordance with the present invention, the above and other objects can be accomplished by the provision of a wireless audio data transmitting and receiving apparatus using human body including: a transmitting unit to convert an audio signal outputted from an audio source using a digital audio interface technology to transmit the converted audio signal through the human body; and a receiving unit to recover the transmitted audio signal transmitted through the human body with the digital audio interface technology to output the recovered audio signal.

The transmitting unit includes: a transmitter electrode contacting the human body; an analog/digital converter to convert the audio signal outputted from the audio source into a digital signal; a digital audio interface transmitter to convert the digital signal converted by the analog/digital converter into a serial digital data containing timing information of a clock; and a transmitter circuit to receive the serial digital data converted by the digital audio interface transmitter and to control the transmitter electrode such that an electric field is induced in the human body.

The receiving unit includes: a receiver electrode contacting the human body; a receiver circuit to receive the serial digital data transmitted from the transmitting unit through the receiver electrode; a digital audio interface receiver to convert the serial digital data received through the receiver circuit to recover the clock and the digital signal; a digital/analog converter to convert the digital signal recovered by the digital audio interface receiver into an analog audio signal; and an amplifier to output the audio signal converted by the digital/analog converter through a speaker.

The transmitting unit includes: a transmitter electrode contacting human body; a digital audio interface transmitter to convert a digital signal outputted from an audio codec of the audio source into frame unit serial digital data containing timing information of a clock; and a transmitter circuit to receive the serial digital data converted by the digital audio interface transmitter and to control the transmitter electrode such that an electric field is induced in the human body.

The receiving unit includes: a receiver electrode contacting the human body; a receiver circuit to receive serial digital data transmitted from the transmitter through the receiver electrode; a digital audio interface receiver to convert the serial digital data received through the receiver circuit to recover the clock and the digital signal; and an audio codec to convert the digital signal recovered by the digital audio interface receiver into an analog audio signal to output the converted analog audio signal through a speaker.

The wireless audio data transmitting and receiving apparatus using human body further includes an input buffer having a baseband filter function, installed at a front side of the analog/digital converter of the transmitting unit.

The digital/analog converter and the amplifier of the receiving unit include plural digital/analog converters and amplifiers respectively such that a stereo signal is separated and outputted.

The digital audio interface transmitter includes an encoder for one of digital audio interface standards among EIAJ CP1201, IEC-60958, AES3, and SPDIF.

The signal transmitted from the transmitter circuit includes a serial digital signal without recovery.

The signal received by the receiver circuit includes a pulse signal having positive and negative width of 5 to 10 ns without a DC offset.

The digital audio interface receiver includes: a recovery circuit to recover the clock and the digital signal; and a decoder for digital audio interface standard to decode the digital signal recovered by the recovery circuit into the digital audio signal.

The transmitter electrode is attached to a rear side of the audio source.

The receiver electrode is attached an earring unit of an earphone.

According to the present invention, an audio signal from an audio source apparatus is converted with a digital audio interface technology and is outputted through a transmission electrode contacting human body to transmit the converted audio signal through the human body as a transmitting medium, the audio signal data transmitted through the human body is received and recovered so that a high quality audio signal outputted from the audio source apparatus can be received to listen to through an earphone, or other device without a wire and/or an antenna.

### BRIEF DESCRIPTION OF THE DRAWINGS

These and/or other objects and advantages of the present invention will become apparent and more readily appreciated from the following description of the embodiments, taken in conjunction with the accompanying drawings, in which:

FIG. 1 is a block diagram illustrating a conventional wireless audio data transmitting and receiving apparatus using a radio frequency signal;

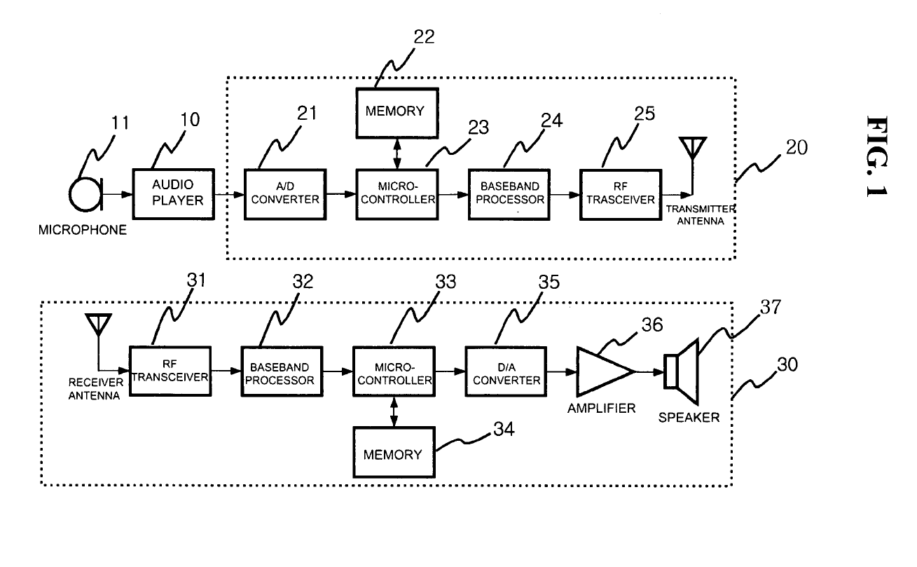

FIG. 2 is a block diagram illustrating a wireless audio data transmitting and receiving apparatus using human body according to an embodiment of the present invention;

FIG. 3 is a block diagram illustrating an audio player employing a transmitting unit of the wireless transmitting and receiving apparatus using human body according to the embodiment of the present invention;

FIG. 4 is a block diagram illustrating an audio earphone employing a receiving unit of the wireless audio data transmitting and receiving apparatus using human body according to the embodiment of the present invention;

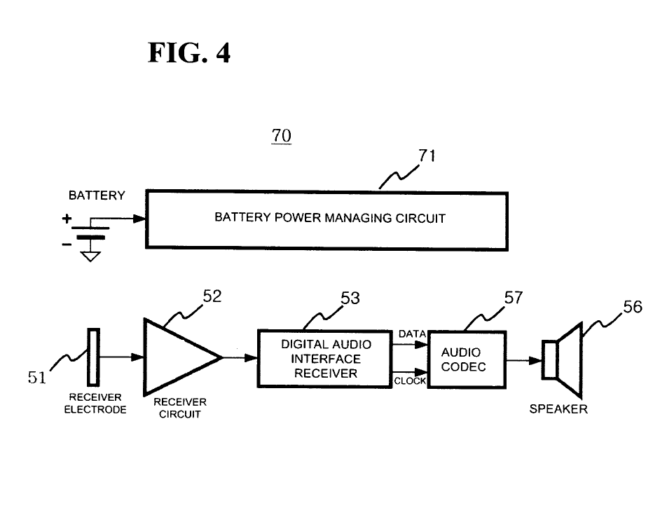

FIG. 5 is a view illustrating an example in which the wireless audio data transmitting and receiving apparatus using human body according to the embodiment of the present invention is applied to an audio player and an earphone; and

FIG. 6 is a view illustrating a use of the wireless audio data transmitting and receiving apparatus using human body according to the embodiment of the present invention.

### DETAILED DESCRIPTION OF THE EMBODIMENTS

Hereinafter, the embodiments of the present invention will be described in detail with reference to accompanying drawings, and it is noted that although similar components are depicted in different drawings, same reference numerals and names are assigned to the similar components. The embodiments of the present invention do not limit the scope of the present invention, but are presented for the exemplary purpose. Modifications and equivalents will be apparent to those skilled in this art within the spirit and scope of the present invention.

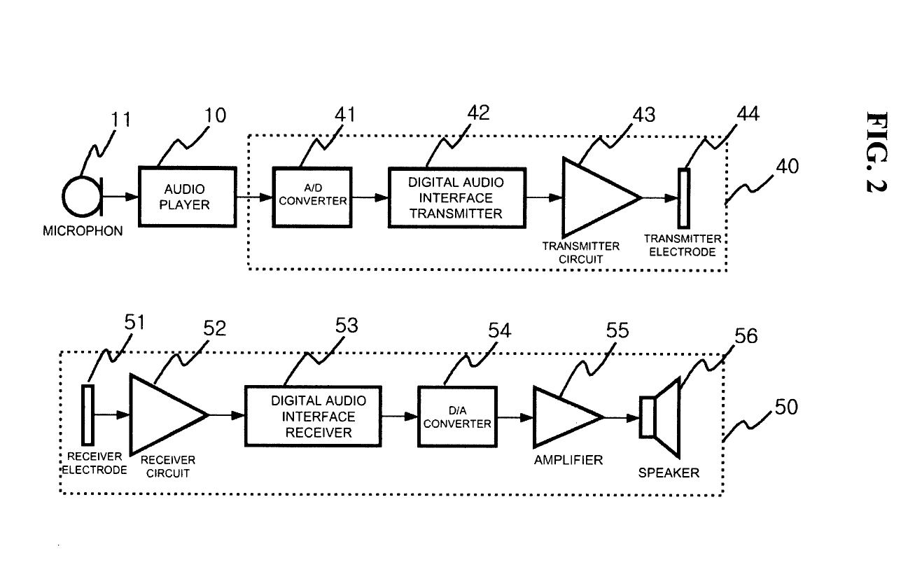

FIG. 2 is a block diagram illustrating a wireless audio data transmitting and receiving apparatus using human body according to an embodiment of the present invention.

As illustrated, a transmitting unit 40 to transmit an audio signal outputted from an audio player 10 includes a transmitter electrode 44 contacting human body, an analog/digital (A/D) converter 41 to convert the audio signal outputted from the audio player 10 into a digital signal, a digital audio interface transmitter 42 to convert the digital signal converted by the A/D converter 41 into frame unit serial digital data containing timing information of a clock, and a transmitter circuit 43 to receive the serial digital data converted by the digital audio interface transmitter 42 and to control the transmitter electrode 44 such that an electric field is induced in the human body.

Moreover, a receiving unit 50 to recover the audio signal transmitted through the human body to listen to includes a receiver electrode 51 contacting the human body, a receiver circuit 52 to receive the serial digital data transmitted from the transmitting unit 40 through the receiver electrode 51, a digital audio interface receiver 53 to convert the serial digital data received through the receiver circuit 52 to recover the clock and the digital signal, a digital/analog (D/A) converter 54 to convert the digital signal recovered by the digital audio interface receiver 53 into an analog audio signal, and an amplifier 55 to output the audio signal converted by the D/A converter 54 through a speaker 56.

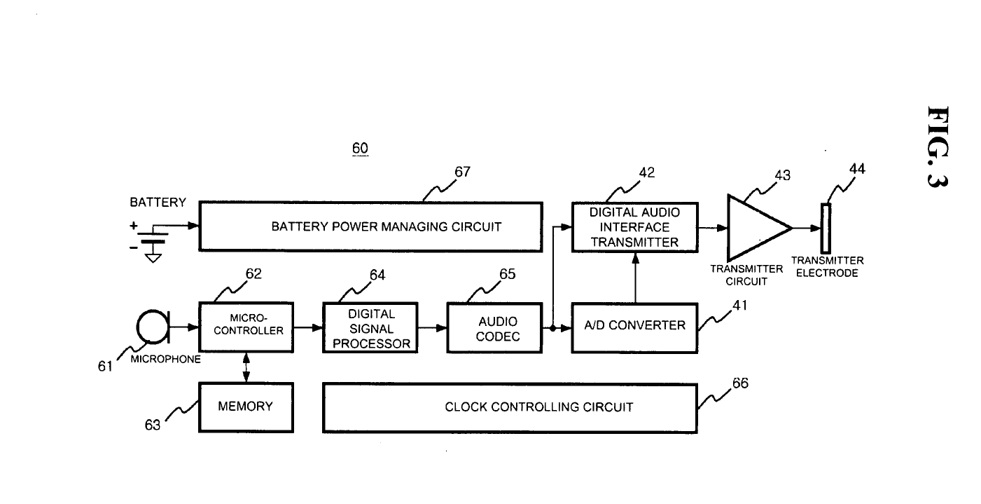

Meanwhile, as illustrated in FIG. 3, an exclusive audio player 60 includes a microphone 61, a microcontroller 62, a memory 63, a digital signal processor 64, an audio codec 65, a clock controller circuit 66, a battery power managing circuit 67, and a battery. The digital audio interface transmitter 42 directly converts the digital audio signal outputted from the audio codec 65 of the exclusive audio player 60 into the frame unit serial digital data containing the timing information of the clock so that the transmitting unit 40 and the A/D converter 41 can be selectively used.

Moreover, the receiving unit 50 may be configured, like the earphone 70, to directly output the audio signal decoded by the digital audio interface receiver 53 to the speaker 56 through the audio codec 57.

In this case, since a clock signal that is required by the digital audio interface receiver 53 is recovered in the earphone 70 so that there is no necessity of additional clock controlling circuit, the battery power managing circuit 71 may be added to the receiving unit in FIG. 2.

Moreover, an input buffer (not shown) serving as a baseband filter is installed at the front side of the A/D converter 41 of the transmitting unit 40 to reduce noise that may cause trouble when the A/D converter 41 samples the audio signal reproduced by the microphone 11, the audio player 10 such as an MP3 player, or the cellular phone in which the microphone 11 or the MP3 player is installed.

The audio interface transmitter 42 includes an encoder (not shown) for a digital audio interface standard, such as Electronic Industries Association of Japan (EIAJ) CP1201, IEC-60958, AES3, and Sony/Philips Digital InterFace (S/PDIF) so that the digital audio signal is encoded into the frame unit serial data containing the timing information compatible with the digital audio interface.

Thus, there is no necessity for additionally transmitting the clock signal for the synchronization between the transmitting end and the receiving end.

Moreover, the digital audio interface receiver 53 includes a recovery circuit (not shown) to recover the clock and the digital signal and a decoder for the digital audio interface standard to decode the digital signal recovered by the recovery circuit into the digital audio signal such that the audio signal encoded by the audio interface transmitter 42 is recovered.

Thus, the digital interface technology for the compatibility with general audio players 10 and the digital pulse technology for the low power and high speed transfer through the human body are used to solve the problems of the conventional apparatus such as the high power consumption, the low transfer rate, and the interference with external noise, so that the high quality audio signal outputted from the portable audio player can be reproduced.

The digital pulse technology is a technology to directly transmit the serial digital signal to the human body without recovery and to receive a pulse signal. Since the human body has an electric property as a broadband pass filter of 100 MHz and the digital signal passing through the human body is converted into a pulse signal having a band width of 5 to 10 ns, if using the electric property of the human body, the digital signal is directly transmitted without the recovery and the recovery and the high speed transfer rate can be obtained. Moreover, since the audio signal is transferred through only the human body as a transmitting medium, the interference due to the external noise can be significantly reduced.

Operation of the wireless audio data transmitting and receiving apparatus using human body according to the embodiment of the present invention will be described as follows.

Since the human body has a component similar to 0.9% saline solution and a weak conductivity according to frequencies, the electric signal can be transferred through the human body and a loss about 5 to 10 dB occurs due to a resistant component of the human body.

Thus, when the transmitter circuit 43 applies a voltage as the digital signal directly to the human body through the transmitter electrode 44, the receiver electrode 51 detects a pulse signal having negative and positive width of 5 to 10 ns without DC offset. This is because the human body has the property of the broadband pass filter with a broadband 100 MHz, the transmitting unit 40 is separated from the ground of the receiving unit 50, and signals including a DC signal, lower than 10 kHz, are not transferred through the human body well.

The very weak electric signal detected in the human body is detected by the receiver circuit 52 having input impedance 50 ohm to be amplified sufficiently and is recovered into the digital signal by triggering.

The digital audio interface receiver 53 includes a clock, a data recovery circuit, and a decoder for the digital audio interface standard to recover and decode the clock signal synchronized with the digital audio interface data stream encoded by the transmitting unit 40 for the recovery of the digital audio signal. The recovered digital audio signal is converted into an analog audio signal by the recovered clock signal or the D/A converter 54, or through the audio codec. 57 so that the converted analog audio signal is outputted through the speaker 56 to listen to.

Thus, the wireless audio data transmitting and receiving apparatus according to the embodiment of the present invention can transfer the audio signal directly at high speed without additional encoding or decoding for the reduction of the transfer rate so that the low power consumption and the minimization can be achieved.

Moreover, the wireless audio data transmitting and receiving apparatus according to the embodiment of the present invention can be attached to the audio player 10 to use, or in order for the minimization, can be installed in the audio player to be served as the exclusive audio player 60.

Meanwhile, if the receiving unit 50 further includes a two channel D/A converter 54 and an amplifier 55 and its transfer rate is increased by two times, the wireless audio data transmitting and receiving apparatus according to the embodiment of the present invention can be used to reproduce the mono-type audio data or the stereo type audio data.

As described above, the wireless audio data transmitting and receiving apparatus using human body according to the embodiment of the present invention can be used in the mono type using a single channel and the stereo type using two channels, and requires double transfer rate.

For example, for a 24-bit A/D converter and the reproduction of a high quality sound, a sampling frequency of 48 kHz is used and a single frame of the digital audio interface data becomes 32-bits. In order to remove the DC component and to easily recover the clock in the digital audio interface receiver 53, duplicated encoding is required.

Thus, in the stereo type, a transfer rate of 6.144 Mb/s (=32-bits/ch*48 kHz/bit*2 ch*2 bits) is required. If the sampling frequency is reduced for the minimum transfer rate, a transfer rate of 2.048 Mb/s, ⅓ of the above transfer rate, is required.

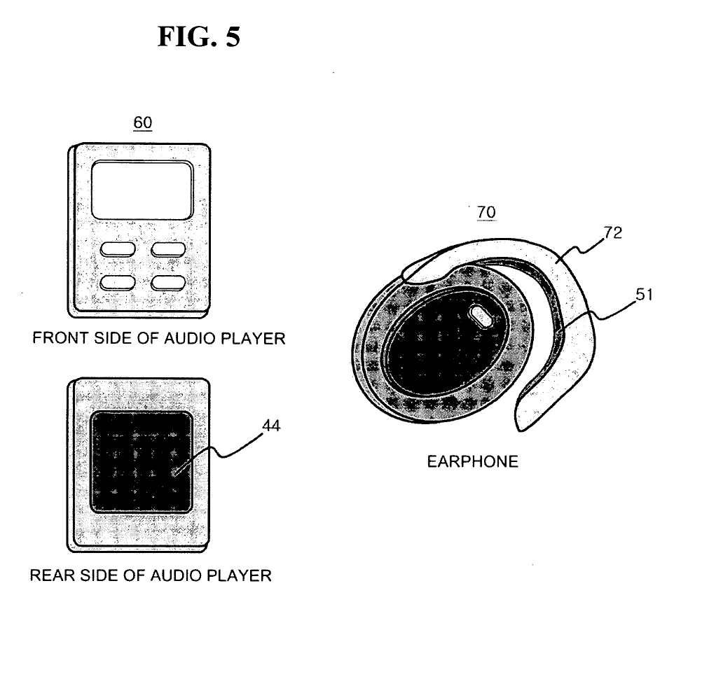

FIG. 5 is a view illustrating an example in which the wireless audio data transmitting and receiving apparatus using human body according to the embodiment of the present invention is applied to the audio player and the earphone.

If the transmitting unit 40 of the wireless audio data transmitting and receiving apparatus according to the embodiment of the present invention is attached to or installed in a general audio player 10, the compatibility is improved but manufacturing costs may be increased and the minimization may be difficult. For low costs, the low power, and the minimization, as illustrated in the drawing, the exclusive audio player 60 using the human body as the audio data transferring medium and an earring-type earphone 70 may be possible.

In this case, it is possible that the transmitter electrode 44 is attached to the rear side of the audio player 60 and the receiver electrode 51 is attached inside of an earring unit 72 of the earring-type earphone 70 such that the earphone 70 contacts the human body easily when wearing the earphone 70.

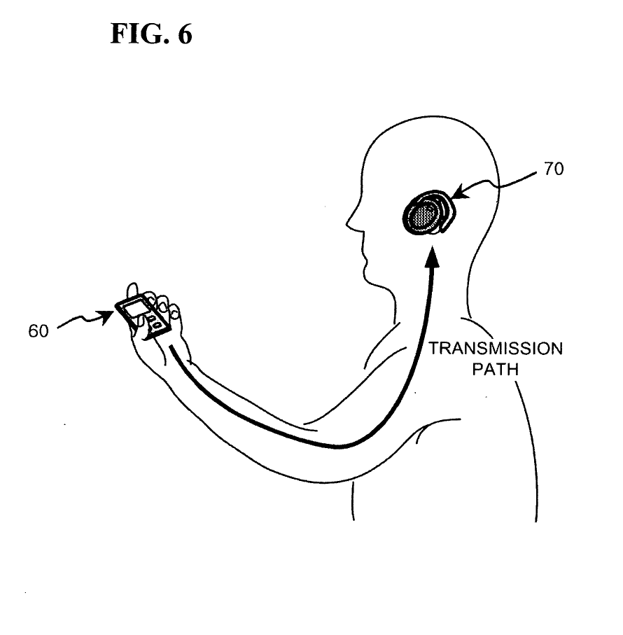

Thus, as an example of a use of the wireless audio data transmitting and receiving apparatus using human body according to the embodiment of the present invention, illustrated in FIG. 6, the user holds the portable exclusive audio player 60 with a hand to wear the earphone 70 around his/her ear(s) so that the use can listen to high quality sound reproduced by the audio player 60.

As described above, according to the present invention, an audio signal outputted from a portable audio player is converted by the digital audio interface technology without a wire or an antenna, is transferred through human body using only a single signal electrode at high speed, and the audio signal transferred through the human body is received to listen through an earphone. Thus, the inconvenient wire is removed to improve the convenience to use and the antenna which has a difficulty due to the size and the installation is not required.

Moreover, since additional encoding and decoding for the reduction of the transfer rate are not required so that the high speed transfer is enabled and the power consumption can be reduced, components and/or a battery can be reduced in size and can be minimized.

In addition, since the audio signal is not transmitted through air but the human body, the external noise interference is less and the transfer error can be reduced so that the user can listen to the high quality sound.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A wireless audio data transmitting and receiving apparatus using human body comprising:
a transmitting unit to convert an audio signal outputted from an audio source using a digital audio interface technology to transmit the converted audio signal through the human body; and
a receiving unit to recover the transmitted audio signal transmitted through the human body with the digital audio interface technology to output the recovered audio signal.

2. The wireless audio data transmitting and receiving apparatus using human body according to claim 1, wherein the transmitting unit comprises:
a transmitter electrode contacting the human body;
an analog/digital converter to convert the audio signal outputted from the audio source into a digital signal;
a digital audio interface transmitter to convert the digital signal converted by the analog/digital converter into a serial digital data containing timing information of a clock; and
a transmitter circuit to receive the serial digital data converted by the digital audio interface transmitter and to control the transmitter electrode such that an electric field is induced in the human body.

3. The wireless audio data transmitting and receiving apparatus using human body according to claim 1, wherein the receiving unit comprises:
a receiver electrode contacting the human body;
a receiver circuit to receive the serial digital data transmitted from the transmitting unit through the receiver electrode;
a digital audio interface receiver to convert the serial digital data received through the receiver circuit to recover the clock and the digital signal;
a digital/analog converter to convert the digital signal recovered by the digital audio interface receiver into an analog audio signal; and
an amplifier to output the audio signal converted by the digital/analog converter through a speaker.

4. The wireless audio data transmitting and receiving apparatus using human body according to claim 1, wherein the transmitting unit comprises:
a transmitter electrode contacting human body;
a digital audio interface transmitter to convert a digital signal outputted from an audio codec of the audio source into frame unit serial digital data containing timing information of a clock; and
a transmitter circuit to receive the serial digital data converted by the digital audio interface transmitter and to control the transmitter electrode such that an electric field is induced in the human body.

5. The wireless audio data transmitting and receiving apparatus using human body according to claim 1, wherein the receiving unit comprises:
a receiver electrode contacting the human body;
a receiver circuit to receive serial digital data transmitted from the transmitter through the receiver electrode;
a digital audio interface receiver to convert the serial digital data received through the receiver circuit to recover the clock and the digital signal; and
an audio codec to convert the digital signal recovered by the digital audio interface receiver into an analog audio signal to output the converted analog audio signal through a speaker.

6. The wireless audio data transmitting and receiving apparatus using human body according to claim 2, further comprising an input buffer having a baseband filter function, installed at a front side of the analog/digital converter of the transmitting unit.

7. The wireless audio data transmitting and receiving apparatus using human body according to claim 3, wherein the digital/analog converter and the amplifier of the receiving unit comprise plural digital/analog converters and amplifiers respectively such that a stereo signal is separated and outputted.

8. The wireless audio data transmitting and receiving apparatus using human body according to claim 2, wherein the digital audio interface transmitter comprises an encoder for one of digital audio interface standards among EIAJ CP1201, IEC-60958, AES3, and SPDIF.

9. The wireless audio data transmitting and receiving apparatus using human body according to claim 2, wherein the signal transmitted from the transmitter circuit comprises a serial digital signal without recovery.

10. The wireless audio data transmitting and receiving apparatus using human body according to claim 3, wherein the signal received by the receiver circuit comprises a pulse signal having positive and negative width of 5 to 10 ns without a DC offset.

11. The wireless audio data transmitting and receiving apparatus using human body according to claim 3, wherein the digital audio interface receiver comprises:
a recovery circuit to recover the clock and the digital signal; and
a decoder for digital audio interface standard to decode the digital signal recovered by the recovery circuit into the digital audio signal.

12. The wireless audio data transmitting and receiving apparatus using human body according to claim 2, wherein the transmitter electrode is attached to a rear side of the audio source.

13. The wireless audio data transmitting and receiving apparatus using human body according to claim 3, wherein the receiver electrode is attached an earring unit of an earphone.

14. The wireless audio data transmitting and receiving apparatus using human body according to claim 4, wherein the digital audio interface transmitter comprises an encoder for one of digital audio interface standards among EIAJ CP1201, IEC-60958, AES3, and SPDIF.

15. The wireless audio data transmitting and receiving apparatus using human body according to claim 4, wherein the signal transmitted from the transmitter circuit comprises a serial digital signal without recovery.

16. The wireless audio data transmitting and receiving apparatus using human body according to claim 5, wherein the signal received by the receiver circuit comprises a pulse signal having positive and negative width of 5 to 10 ns without a DC offset.

17. The wireless audio data transmitting and receiving apparatus using human body according to claim 5, wherein the digital audio interface receiver comprises:
a recovery circuit to recover the clock and the digital signal; and
a decoder for digital audio interface standard to decode the digital signal recovered by the recovery circuit into the digital audio signal.

18. The wireless audio data transmitting and receiving apparatus using human body according to claim 4, wherein the transmitter electrode is attached to a rear side of the audio source.

19. The wireless audio data transmitting and receiving apparatus using human body according to claim 5, wherein the receiver electrode is attached an earring unit of an earphone.
